(19) United States
(12) Patent Application Publication
(10) Pub. No.: US 2010/0136233 A1
(43) Pub. Date: Jun. 3, 2010

(54) OBLIQUE VACUUM DEPOSITION FOR ROLL-ROLL COATING OF WIRE GRID POLARIZER LINES ORIENTED IN A DOWN-WEB DIRECTION

(76) Inventor: Michael J. Little, Garden Valley, CA (US)

Correspondence Address: LUMEN PATENT FIRM, 350 Cambridge Avenue, Suite 100, PALO ALTO, CA, 94306, US

(21) Appl. No.: 12/733,036

(22) PCT Filed: Jul. 24, 2008
(86) PCT No.: PCT/US2008/071080

§ 371 Date: Feb. 2, 2010

Related U.S. Application Data
(60) Provisional application No. 60/953,658, filed on Aug. 2, 2007.
(60) Provisional application No. 60/953,668, filed on Aug. 2, 2007.
(60) Provisional application No. 60/953,671, filed on Aug. 2, 2007.

(51) Int. Cl. C23C 16/44; C23C 16/00

(52) U.S. Cl. 427/248.1; 118/715

(57) ABSTRACT

Material may be obliquely deposited on a plurality of down-web oriented features on a substrate oriented in a down-web (z) direction or other than a cross-web (y) direction. A linear source generates a vapor flux of a material oriented parallel to the substrate and either parallel to the y direction or at an angle intermediate the y and z directions. The vapor flux impinges on the substrate at an oblique angle relative to the y direction. The substrate moves in the z direction relative to the linear source as the material impinges on the substrate. The vapor flux has a sufficiently narrow angular distribution in a plane perpendicular the substrate and parallel to the y direction that material deposits on predetermined portions of the down-web oriented features but not other portions, forming parallel down-web oriented lines of the material on the substrate.

### CLAIM OF PRIORITY

This application clams the benefit of priority of U.S. Provisional Patent Application No. 60/953,668, filed Aug. 2, 2008, the entire contents of which are incorporated herein by reference.

This application clams the benefit of priority of U.S. Provisional Patent Application No. 60/953,652, filed Aug. 2, 2008, the entire contents of which are incorporated herein by reference.

This application clams the benefit of priority of U.S. Provisional Patent Application No. 60/953,658, filed Aug. 2, 2008, the entire contents of which are incorporated herein by reference.

This application clams the benefit of priority of U.S. Provisional Patent Application No. 60/953,671, filed Aug. 2, 2008, the entire contents of which are incorporated herein by reference.

### CROSS-REFERENCE TO RELATED APPLICATIONS

This application is related to International Patent Application PCT ______, (Attorney Docket Number AGT-004/PCT, to Michael J. Little, entitled “NANOEMBOSSED SHAPES AND FABRICATION METHODS OF WIRE GRID POLARIZERS”, filed the same day as the present application, the entire contents of which are incorporated herein by reference.

This application is related to International Patent Application PCT ______, (Attorney Docket Number AGT-005/PCT, to Michael J. Little, entitled “A WIRE GRID POLARIZER WITH COMBINED FUNCTIONALITY FOR LIQUID CRYSTAL DISPLAYS”, filed the same day as the present application, the entire contents of which are incorporated herein by reference.

### FIELD OF THE INVENTION

Embodiments of the present invention generally relate to continuous roll to roll vacuum deposition of thin metal films onto linear ridge and valley surface topography features and more specifically to vacuum depositing metal onto ridge and valley surface features when their principle orientation is in a down-web direction.

### BACKGROUND OF THE INVENTION

Liquid crystal displays (LCDs) have recently emerged to become the dominant display technology for graphical images and video. This dominant position has been enabled by numerous innovations that have been introduced to overcome several limitations of LCDs such as low optical efficiency and poor angular viewing characteristics.

The schematic illustration of the construction of a basic LCD 10 shown in FIG. 1 highlights the 2 main subassemblies of a LCD; the backlight 100 and the LC panel 20. The backlight 100 provides unpolarized light 40 to the LC panel 20. Traditionally the rear polarizer 50 absorbs one plane of polarization and transmits the desired plane of polarization. This is one of the major causes of poor optical efficiency; more than ½ of the light generated by the backlight is absorbed by the rear polarizer 50 and is lost forever.

The poor angular viewing characteristics of LCD result from the birefringence of the liquid crystal layer 80. When a voltage is applied to the liquid crystal layer, the liquid crystal molecules re-orient relative to the surface normal direction, typically in an asymmetric pattern; this molecular alignment asymmetry results in an optical birefringence asymmetry with respect to the surface normal. Thus, the optical properties of the LCD depend on the off-normal viewing angle due to the induced asymmetric birefringence of the liquid crystal layer 80.

The angular viewing limitations of LCDs have substantially been overcome by the introduction of additional layers known as compensation films or retarder films. These compensation films 60 and 62, which are inserted between the polarizers 50 and 52 and the liquid crystal layer 80, are designed to provide the inverse of the birefringence vs. angle effects of the liquid crystal layer and thereby cancel or compensate for their effects. Compensation films are described more fully in U.S. Pat. Nos. 5,583,679 5,619,352 and 5,853,801.

To minimize LCD assembly costs, polarizer manufacturers typically laminate their absorptive polarizers 50 together with an appropriate compensation film 60 to provide the LCD manufacturers with a single multifunctional film. However, both of these films which are manufactured on roll-to-roll fabrication machines, have principal optical axes which must be precisely aligned with each other when laminating. To further minimize costs, it is desired to laminate the absorptive polarizer and the compensation films with roll to roll processing equipment. To facilitate this, substantially all of the absorptive polarizer films and the compensation films are manufactured with their principal optical axis oriented in a down web direction on the roll to roll fabrication equipment.

To address the poor optical efficiency limitation of LCDs, new high contrast reflective polarizers known as wire grid polarizers are being introduced to replace the rear absorptive polarizer 50. By reflecting the unwanted plane of polarization rather than absorbing it, wire grid polarizers enable the unwanted plane of polarization to be converted into the desired plane of polarization and thereby positively contribute to the brightness of the LCD. Brightness improvements of 60% (i.e., recovery of over one half of the light traditionally absorbed) have been achieved with this polarization recycling technique. Wire grid polarizers are described in more detail in U.S. Pat. Nos. 6,122,103 and 6,243,199.

Prior art wire grid polarizer fabrication techniques on roll to roll fabrication equipment have been limited to fabricating wire grid polarizers with their principal optical axis oriented in a cross web direction (see for example U.S. Pat. Nos. 3,046,839, 6,375,870 and US Patent Application Publications 20060118514 and 20060159958. The entire contents of all of the foregoing patents and publications are incorporated herein by reference. However, wire grid polarizers manufactured with principal axis oriented in the cross web direction can not directly fit into the very large installed LCD infrastructure such as lamination to compensation films on roll to roll processing equipment.

Thus, it would be desirable to provide a method for fabricating wire grid polarizers on roll to roll processing equipment such that the principal optical axis of the wire grid polarizer is oriented substantially in the down web direction thereby matching the orientation of the principle axis of compensation films and enabling roll-roll lamination of wire grid polarizers to compensation films.

### BRIEF DESCRIPTION OF THE DRAWINGS

FIG. 1 is a schematic illustration of the construction of a basic liquid crystal display (LCD).

FIG. 2 is a schematic description of a wire grid polarizer.

FIG. 3 is an illustration of the prior art technique of oblique deposition of metal onto ridge and valley surface topography to form a wire grid polarizer.

FIG. 4 is an illustration of prior art metal deposition onto cross-web oriented ridge and valley surface topography.

FIG. 5 is an illustration of prior art roll to roll deposition of metal on cross-web oriented ridge and valley surface features.

FIG. 6 is an illustration of down-web oriented ridge and valley surface features

FIG. 7 is an illustration of prior art configuration of oblique material deposition onto down-web oriented ridge and valley surface features.

FIG. 8 is an illustration of oblique material deposition with geometry modified for down-web oriented ridge and valley surface features.

FIGS. 9A-9B illustrate an embodiment of oblique material deposition baffling geometry for down-web oriented ridge and valley surface features.

FIG. 10 is an illustration of a striped shadowing effect with an embodiment of oblique material deposition baffling geometry for down-web oriented ridge and valley surface features.

FIG. 11 is an illustration of a preferred embodiment of a source baffle with tilted baffles.

FIG. 12. is an illustration of a preferred embodiment of a source baffle arrangement with tilted baffles for producing uniform thickness oblique metal for down-web oriented ridge and valley surface features.

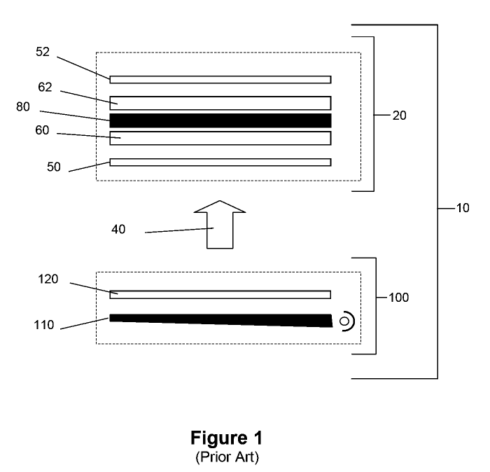

### SUMMARY OF THE INVENTION

In view of the foregoing, there is a need for a method and apparatus for obliquely depositing a coating with a roll to roll continuous process where the substrate has surface features that can be oriented in other than a cross-web direction.

### DETAILED DESCRIPTION OF THE SPECIFIC EMBODIMENTS

Continuous roll to roll vacuum deposition of thin films is widely used as a low cost manufacturing method. Systems for the continuous roll to roll vacuum deposition of metal are commercially available from Leybold Optics (e.g., as described in http://www.levboldoptics.com/pdf/cap-m en.pdf, which is incorporated herein by reference), Applied Films (e.g., as described in http://www.appliedmaterials.com/products/web multimet 3.html?menulD=9 2 1, which is incorporated herein by reference), CHA Industries (e.g., as described in http://www.chaindustries.com/markroll.html, which is incorporated herein by reference) and others. However, to achieve high coating efficiency these systems are designed such that the material being deposited is incident on the substrate, typically a thin plastic film, from the entire range of source trajectory angles available from the deposition source. As such, with out modifications, these broad angle vapor streams are not suitable for applications using oblique angle deposition to achieve shadowing effects.

An innovative technique for making wire grid polarizers and other devices is the use of oblique angle deposition to selectively coat topographical surface features such as ridge and valley surface features while leaving the opposite side uncoated due to shadowing effects (see for example US Patent Application Publications 20060118514 and 20060159958, both of which are incorporated herein by reference). This technique of selectively coating surface features on one side (the side facing the vapor source) and not on the opposite side (the side facing away from the vapor source) has been referred to as oblique angle deposition or simply oblique deposition; in effect it is a self shadowing technique. Because of their broad range of deposition angles, the commercially available roll to roll vacuum deposition systems cannot be used as is for oblique deposition.

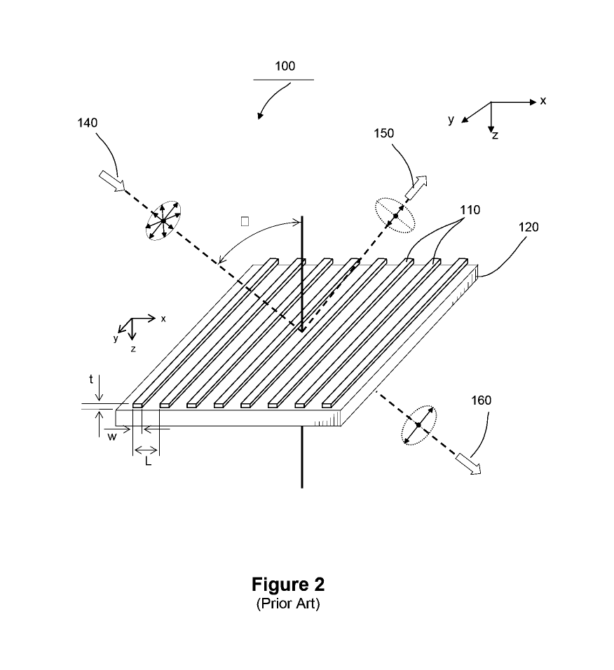

A wire grid polarizer consists of closely spaced parallel conductive lines fabricated on a transparent substrate (see FIG. 2). When the periodicity of the metal lines L is several times smaller than the wavelength of light, one plane of polarization 150 is reflected while an orthogonal plane of polarization 160 is transmitted. This simple repetitive structure is most economically fabricated with an oblique deposition technique onto a substrate with requisite ridge and valley surface topography.

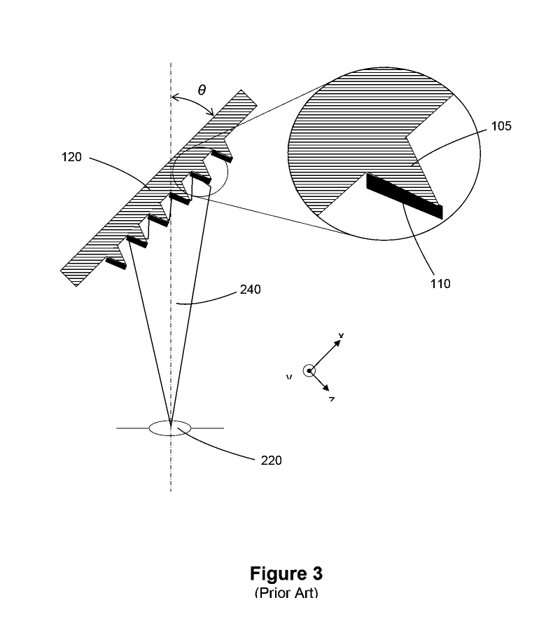

The coating geometry for fabricating a wire grid polarizer using oblique deposition is schematically illustrated in FIG. 3. A vapor flux 240 emanating from the source 220 is directed towards a substrate that is disposed at an oblique angle θ. As illustrated in the inset, this deposition geometry creates a coating 110 on downward facing sides of the surface features 105 while the upward facing sides of 105 are not exposed to the vapor flux and receive no deposit. This simple process is the most economical method to fabricate wire grid polarizers.

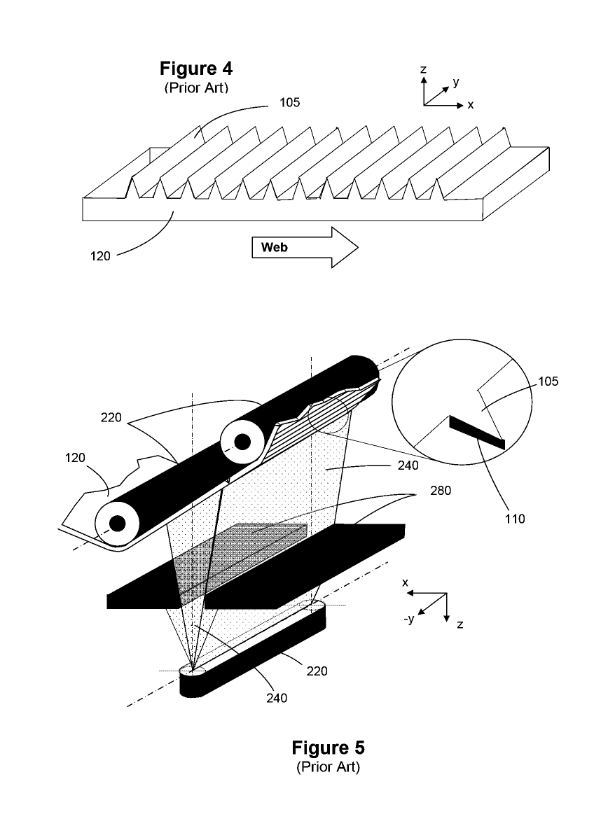

A more detailed view of this process is illustrated in the perspective drawings of FIGS. 4 and 5. In FIG. 4, the prior art cross-web orientation of the surface topography features 105 are explicitly shown relative to the web direction. The ridge and valley surface features 105 are oriented in the y-direction and the substrate web 120 is running in the x-direction. A perspective view of the deposition geometry used in the prior art is shown in FIG. 5. A linear source of material to be deposited 220 that is oriented in the y-direction, i.e., parallel to the orientation of the ridge and valley surface features on the substrate web 120 which is inclined at an oblique angle θ relative to the source 220. The angular extent of the vapor flux of the metal being deposited 240 is restricted to the desired range by aperture plates 280. This prior art geometry produces the desired result shown in the inset; metal coating 110 deposited onto one face of the ridge and valley surface features 105.

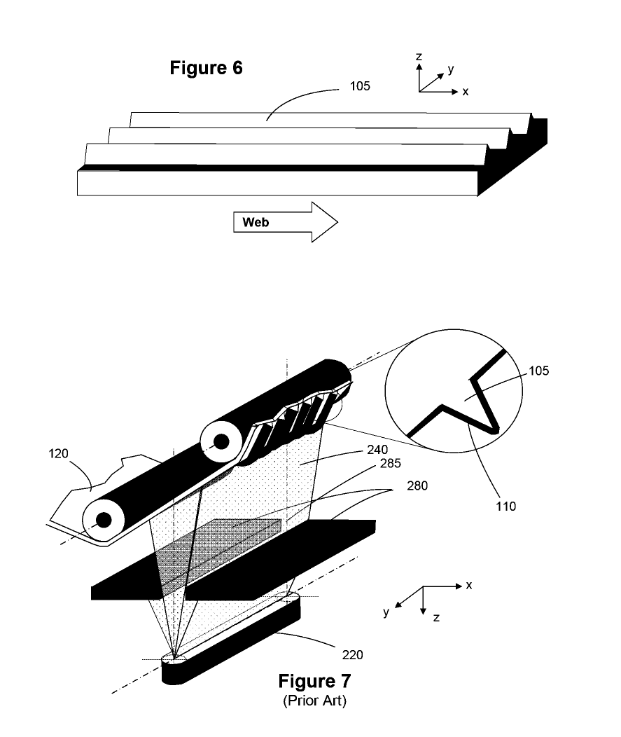

However, as shown in FIG. 6 the oblique angle deposition configuration illustrated in FIG. 5 will not work if the ridge and valley surface features are oriented in a down-web direction. This problem is illustrated in FIG. 7. The narrow aperture between aperture plates 280 restricts the angular distribution of the deposition flux to a narrow range of angles in the x-z plane. However, the length of the aperture between aperture plates produces a very broad angular flux distribution in the y-z plane. With ridge and valley surface features oriented in the down-web direction, the x-direction, the broad angular flux distribution in the y-z plane results in all surfaces of the ridge and valley structures being coated with metal as illustrated in the inset of FIG. 7. No oblique angle shadowing effect is present and the desired separated parallel conductive lines that are necessary for a wire grid polarizer are not formed.

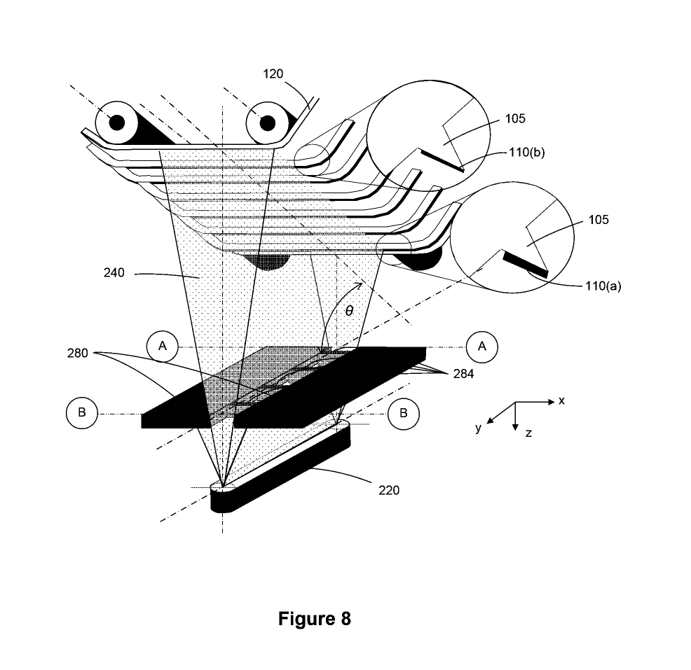

One way of modifying the prior art deposition geometry that would enable the formation of the desired separated lines of material on down-web oriented ridge and valley surface features is shown in FIG. 8 which illustrates an oblique deposition method and apparatus according to an embodiment of this invention. In FIG. 8 the linear source of material to be deposited is shifted longitudinally in the y-direction. This longitudinal shift coupled with the use of an angled baffle plate like the one illustrated in FIG. 8 limits the angle of incidence of the vapor flux in the y-z plane and therefore enables the use of oblique deposition in other than cross-web orientated surface features.

By way of example, and not by way of limitation, the material being deposited may be a metal, such as aluminum, silver or combinations of the two. Other metals and other materials may be obliquely deposited on ridge and valley features oriented in a down-web direction. For wire grid polarizer fabrication a periodicity of the ridge and valley structures may range from 85 nm to 200 nm, preferably from 100 nm to 150 nm. For wire grid polarizer fabrication, a height of the ridge and valley features may range from 75 nm to 250 nm, preferably from 100 nm to 150 nm.

As seen in FIG. 8, a linear deposition source 220 is oriented in a cross-web (y) direction and the plane substrate web 120 is tilted about an axis perpendicular to the y direction by the oblique angle θ. By tilting the substrate web 120 in the y-z plane and adding a series of down-web oriented baffles 284 between the aperture plates 280 to restrict the angular flux distribution in the y-z plane the narrow angular flux distribution results in the desired shadowing effects. If the baffles 284 were absent, deposition material emanating from the forward end of the source 240 as indicated by the B-B line would be able to deposit on the backside of the ridge and valley structures near the distal end of the source as indicated by the A-A line.

It is desirable to keep the baffles 284 as thin as possible to minimize blocking the vapor flux. The baffles 284 may be made as thin as practical, preferably from 0.2 mm to 5.0 mm thick. The height of the baffles may range from 10 mm to 60 mm, preferably from 20 mm to 40 mm. The baffles may be regularly spaced such that adjacent baffles are separated by an aperture between 2 mm to 40 mm wide, preferably from 5 mm to 15 mm wide. In addition, the outboard ends of each of the baffles 284 may be attached to a mechanical support that also serves as a means to dissipate heat, such as water cooled channels.

The use of baffles to control the angular distribution of a deposition flux is well known (see for example U.S. Pat. Nos. 5,597,462 and 6,730,197, the disclosures of both of which are incorporated herein by reference). However, the combination of tilting a web substrate with down-web oriented ridge and valley features relative to a baffled source as described herein is believed to be both new and unobvious.

A potential problem with the configuration illustrated in FIG. 8 for oblique angle deposition of material onto surface topography oriented in the down web direction is the uniformity of the coating thickness in the cross-web direction (i.e., the y-direction). The distance from the source to the substrate at the A-A distal end is much shorter than the distance from the source to the substrate at the forward end B-B. With typical web widths of 1 meter or more and typical oblique angles of 45° or more, the difference in source to substrate distance between the forward and distal ends may be greater than 1 meter. Such a large difference in source to substrate distance may result in unacceptably large thickness variations in the thickness of the material deposited.

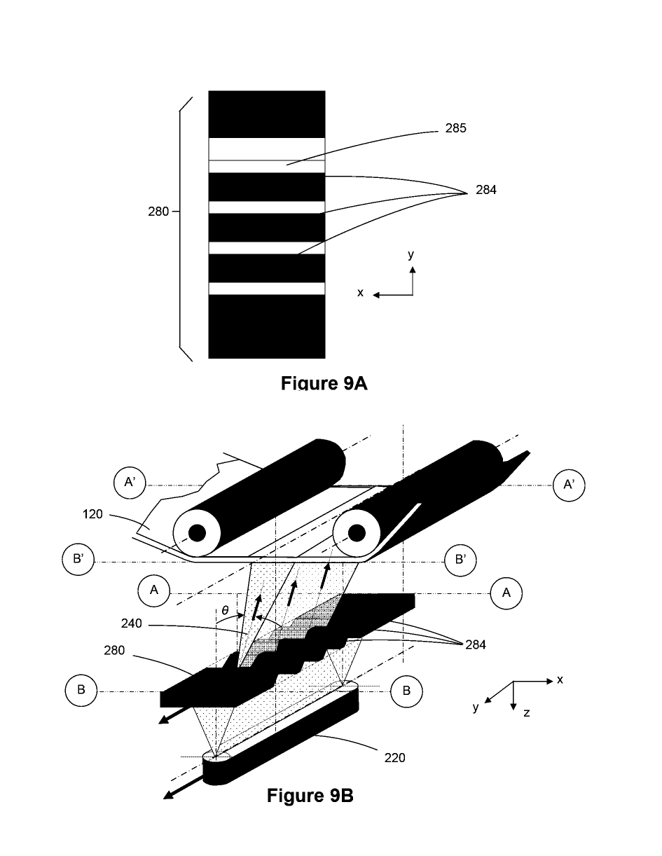

An apparatus and method according to a preferred embodiment of the present invention that overcomes this potential cross-web thickness uniformity problem is illustrated in FIGS. 9A-9B. The oblique angle deposition configuration illustrated in FIG. 9B achieves a uniform coating thickness across the web by maintaining a constant distance between the source 220 and the substrate 120. The baffles 284 are tilted in the y-z plane by an angle θ with respect to the x-z plane relative to the source 220 to provide the desired angular flux direction θ relative to the substrate required for oblique angle shadowing effects. This tilts the aperture 285 between adjacent baffles and narrows the angular spread of the flux of material from the source 220. The height and width (spacing) of the baffles 284 dictates the narrowness of the angular spread of angular distribution of the deposition flux. To enable the angled trajectory of the deposition flux 240 to intercept the full width of the substrate web 120, the baffle plate 280 and the linear source 220 are both translated in the y-direction (moved forward in the drawing) such that the forward end of the pair as indicated by the line B-B is offset vertically from the forward edge of the substrate web 120 as indicated by the line B′-B′. Thus, the deposition apparatus illustrated in FIGS. 9A-9B may overcome potential problems that may be associated with the deposition configuration that was illustrated in FIG. 8.

Under some circumstances, the deposition configuration illustrated in FIGS. 9A-9B may result in a periodic variation in the thickness of the deposited film in the cross-web direction (the y-direction). If the angled baffles are oriented perpendicular to the longitudinal axis of the baffle plate (the y-axis) the thickness (in the y-direction) of each of the baffles will produce a shadow on the vapor flux as it exits the baffle. This would result in a non-uniformity of the vapor flux along the y-direction which would in turn cause a thickness variation (non-uniformity) in the y-direction but this is the cross-web direction. Thus, the deposited coating will have stripes (one stripe for each baffle) resulting from a pattern of variation in coating thickness in the cross-web direction.

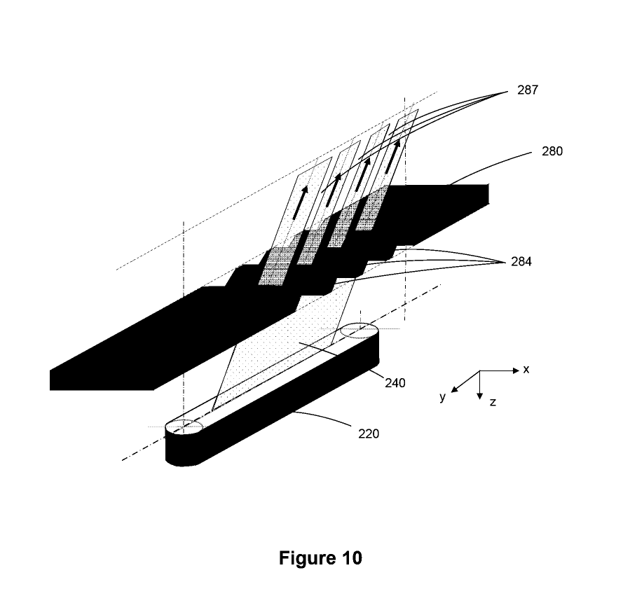

This problem can be visualized by referring to FIG. 10. In FIG. 10 each of the baffles 284 casts a shadow 287 that diminishes the flux immediately above the baffles. To avoid a reduction in the metal thickness in these shadow regions, the distance between the baffles and the substrate must be large enough for there to be sufficient mixing of the deposition flux from adjacent baffle openings to avoid the periodic variations of deposition flux in the cross-web direction.

The foregoing problem may be eliminated by inclining the baffles at a slant angle φ about an axis perpendicular to a plane parallel to the y and z directions. With slanted baffles, as the roll of material traverses each of the individual baffles the vapor flux shadow appears at a different cross-web position and thus integrates the effect of the baffles over the entire width of the web. This eliminates the stripes of thickness variation.

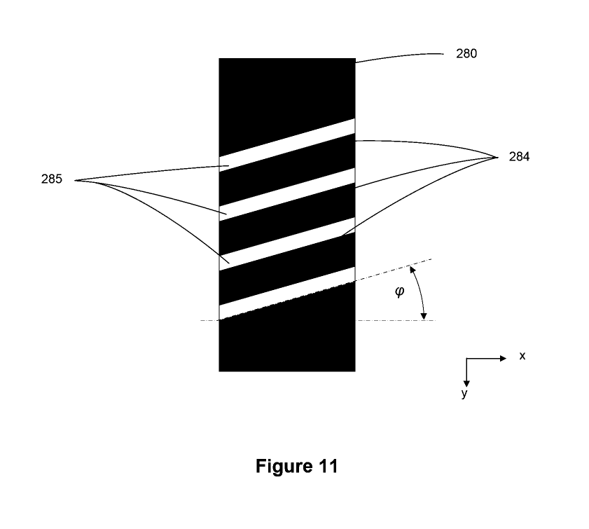

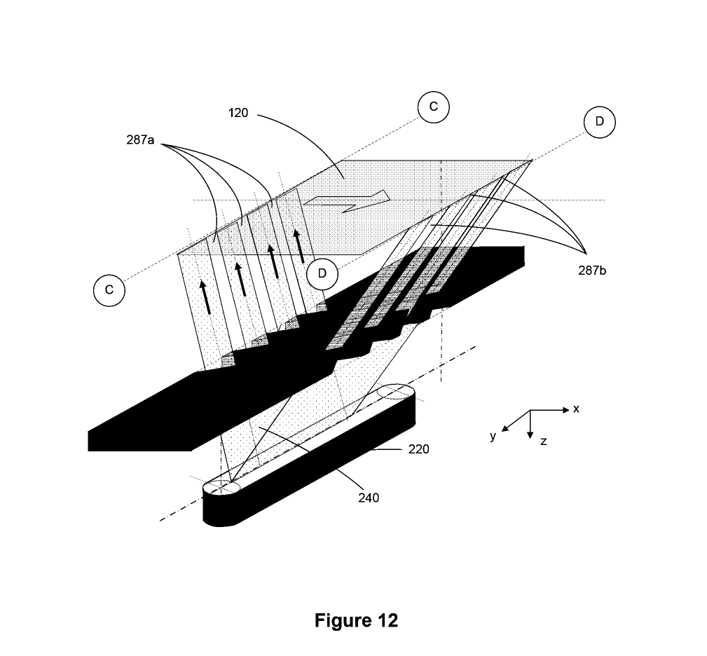

By way of example, and not by way of limitation, an improved apparatus utilizing a baffling plate 280 having slanted baffles 284 is illustrated in FIG. 11 and FIG. 12. The baffles 284 in this improved version remain tilted at an angle 8 relative to the y-z plane as before. However, the baffles 284 are inclined at a slant angle φ about an x axis perpendicular to the y-z plane. The baffle slant angle φ may be in a range of 0° to 45°, preferably in a range of 0° to 25°. By slanting and tilting the baffles 284, the location of the shadow behind each baffle varies across the width of the baffle plate 280. Thus, the location of the flux shadow in the cross-web direction (the y-direction) varies from point to point as the substrate travels in the web direction (the x direction). This blurring of the baffle shadows can be visualized more clearly by referring to FIG. 12. When the substrate web enters the deposition widow indicated by the C-C line in FIG. 12, the baffle shadows 287a are located as indicated relative to the forward edge of the substrate web 120. Upon exiting the deposition window as indicated by the line D-D, the baffle shadows 287b are located at the positions indicated relative to the rear edge of the substrate web. As can be seen from FIG. 12, the position of the baffle shadows in the y-direction change continuously in the cross-web direction (the y-direction) as the substrate web traverses the deposition window in the x-direction.

Thus, the innovative deposition configurations illustrated in FIG. 9 and FIG. 12 enable the oblique angle deposition of metal on ridge and valley surface features that are oriented substantially in the down web direction. While it is not shown, it is anticipated that this approach would be suitable for ridge and valley features that are skewed from exactly being in exactly in the down web direction (x-direction) by as much as 30°.

In embodiments of the present invention, oblique deposition may take place at a deposition angle θ in a range from 30° to 60°, more preferably from 45° to 55°. Such an angle may be obtained by appropriate tilting of the baffles 284 or by suitable offset of the source 220 in the cross-web (y) direction or a combination of both. Material may be deposited to any suitable thickness. For wire grid polarizers, electrically conductive material, e.g., metal is preferably deposited to a thickness in a range of 20 nm to 200 nm, preferably from 50 nm to 150 nm. The distance between the source 220 and the web substrate 120 may range from 0.2 m to 1.0 m, preferably about 0.4 m.

By way of example, and not by way of limitation, down-web oriented features may be formed on the substrate 120 by embossing with a roller. The embossing roller may be oriented with its rotation axis substantially perpendicular to the down-web direction relative to the substrate 220. The embossing roller may have regularly spaced ridge and valley structures, e.g., circumferential grooves, e.g., 85 nm to 200 nm apart, preferably from 100 nm to 150 nm apart and less than about 50 nanometers in width. The circumferential grooves may be oriented substantially perpendicular to the rotation axis and substantially parallel to the down-web direction. As the embossing roller rotates it may be pressed into a layer of photosensitive monomer on a substrate as the substrate moves past the roller in the down-web direction. The rotation rate of the roller may be controller to match the translation speed of the substrate. The region of the coating pressed by the roller may be exposed to light in sufficient amount to polymerize the coating before the roller pressure is released.

The description above describes the situation where the two preferred alignment directions are brought into coincidence, i.e., made substantially parallel. It is anticipated in this invention that it may be desirable to have an angle other than zero (i.e., coincident) between the pre-existing orientation of the separate film and that of the obliquely deposited film to be laminated to it.

What is claimed is:

1. A method for oblique deposition of material on a plurality of down-web oriented features on a substrate oriented in a down-web (z) direction or other than a cross-web (y) direction, comprising:
a) generating a vapor flux of a material to be deposited on the substrate from a linear source, wherein the linear source is oriented parallel to the substrate and either parallel to the y direction or at an angle intermediate the y and z directions;
b) impinging the vapor flux on the substrate at an oblique angle 8 relative to the y direction; and
c) moving the substrate in the z direction with respect to said linear source as the material from the vapor flux impinges on the substrate,
wherein the vapor flux has a sufficiently narrow angular distribution in a plane perpendicular to the substrate and parallel to the y direction that the material deposits on predetermined portions of the down-web oriented features but not other portions, thereby forming a plurality of parallel down-web oriented lines of the material on the substrate.

2. The method of claim 1 wherein said substrate is tilted about an axis parallel to the z direction by the oblique angle 8 relative to the linear source.

3. The method of claim 2, wherein b) includes passing the vapor flux from the linear source through a linear aperture located between the linear source and the substrate, wherein the aperture includes one or more baffles oriented parallel to the z direction.

4. The method of claim 3 wherein a number, height or spacing of the baffles is sufficient to restrict the angular distribution of the vapor flux in the plane perpendicular to the substrate and parallel to the y direction.

5. The method of claim 1, wherein a center of the linear source is longitudinally offset in the cross-web (y) direction relative to a center of the substrate by a sufficient amount that the vapor flux impinges on the substrate at the oblique angle θ relative to the y direction.

6. The method of claim 5, wherein b) includes passing the vapor flux from the linear source through one or more baffles located between the linear source and the substrate, wherein the one or more baffles are oriented parallel to the z direction and tilted with respect to the y direction by the oblique angle 8.

7. The method of claim 6 wherein a number, height or spacing of the one or more baffles is sufficient to restrict the angular distribution of the vapor flux in the plane perpendicular to the substrate and parallel to the y direction.

8. The method of claim 6 wherein a distance between the one or more baffles and the substrate is large enough for there to be sufficient mixing of deposition flux from adjacent baffle openings to avoid periodic variations the cross-web direction of the deposition of the material on the substrate.

9. The method of claim 6 wherein the one or more baffles are inclined at a slant angle φ about an axis perpendicular plane parallel to the y and z directions.

10. The method of claim 1 wherein a periodicity of the down web oriented features is in a range of 85 nm to 200 nm.

11. The method of claim 10 wherein a periodicity of the down web oriented features is in a range of 100 nm to 150 nm.

12. The method of claim 10 wherein a height of the down web oriented features is in a range of 75 nm to 250 nm.

13. The method of claim 10 wherein a height of the down web oriented features is in a range of 100 nm to 150 nm

14. In a roll-to-roll process involving formation of features on a substrate in the form of a roll of material, a method for oblique evaporation on features on a oriented in a down-web (x) direction of the substrate, comprising, depositing material from a linear source of material to be deposited that is shifted longitudinally in a cross-web (y) direction relative to the substrate, wherein the material is deposited through an angled baffle disposed between the source and the substrate, the angled baffle having a plurality of angled baffle plates oriented in a down-web direction to limit an angle of incidence of a vapor flux in the y-z plane and thereby enable the use of oblique deposition on other than cross-web orientated surface features.

15. An apparatus for oblique evaporation of material on a plurality of down-web oriented features on a substrate oriented in a down-web (z) direction or other than a cross-web (y) direction, comprising:
a) a linear vapor source adapted to generate a vapor flux of a material to be deposited on the substrate as the substrate moves relative to the vapor source in the z direction, wherein the linear source is oriented parallel to the substrate and either parallel to the y direction or at an angle intermediate the y and z directions, wherein a center of the linear source is longitudinally offset in the y direction relative to a center of the substrate by a sufficient amount that the vapor flux impinges on the substrate at the oblique angle 8 relative to the y direction; and
b) one or more baffles located between the linear source and the substrate, wherein the one or more baffles are oriented parallel to the z direction and tilted with respect to the y direction by the oblique angle θ.

16. The apparatus of claim 15 wherein a number, height or spacing of the one or more baffles is sufficient to restrict the angular distribution of the vapor flux in the plane perpendicular to the substrate and parallel to the y direction.

17. The apparatus of claim 15 wherein a distance between the one or more baffles and the substrate is large enough for there to be sufficient mixing of deposition flux from adjacent baffle openings to avoid periodic variations the cross-web direction of the deposition of the material on the substrate.

18. The apparatus of claim 15 wherein the one or more baffles are inclined at a slant angle φ about an axis perpendicular plane parallel to the y and z directions.

19. An apparatus for oblique evaporation of material on a plurality of down-web oriented features on a substrate oriented in a down-web (z) direction or other than a cross-web (y) direction, comprising:
a) a linear vapor source adapted to generate a vapor flux of a material to be deposited on the substrate as the substrate moves relative to the vapor source in the z direction, wherein the linear source is oriented parallel to the y direction and tilted about an axis parallel to the z direction by an oblique angle θ relative to the substrate;
b) an aperture located between the linear source and the substrate; and
c) one or more baffles disposed within the linear aperture, wherein the one or more baffles are oriented parallel to the z direction.

20. The apparatus of claim 19 wherein a number, height or spacing of the baffles is sufficient to restrict the angular distribution of the vapor flux in the plane perpendicular to the substrate and parallel to the y direction.

21. The apparatus of claim 19 wherein the linear aperture is oriented parallel to the linear source.
